(19) United States
(12) Patent Application Publication
(10) Pub. No.: US 2019/0288677 A1
(43) Pub. Date: Sep. 19, 2019

(54) SEMICONDUCTOR DEVICE AND APPARATUS

(71) Applicant: FUJI ELECTRIC CO., LTD., Kanagawa (JP)

(72) Inventor: Yasuki YOSHIDA, Matsumoto-city (JP)

(21) Appl. No.: 16/258,641

(22) Filed: Jan. 27, 2019

(30) Foreign Application Priority Data
Mar. 14, 2018 (JP) 2018-047043

(51) Int. Cl. H03K 17/082; H01L 23/62; H01L 23/495; H01L 23/64; H01L 27/07

(52) U.S. Cl. CPC H03K 17/0822; H01L 23/62; H01L 29/866; H01L 23/645; H01L 27/0727; H01L 23/49575

(57) ABSTRACT

A semiconductor device including: a semiconductor switch; an exterior body housing the semiconductor switch; a drain terminal that is electrically connected to a drain of the semiconductor switch and exposed through the exterior body; a plurality of voltage clamp devices that are cascade-connected between the drain terminal and a gate of the semiconductor switch; and a voltage clamp terminal that is electrically connected between two of the plurality of voltage clamp devices and exposed through the exterior body, is provided.

The contents of the following Japanese patent application are incorporated herein by reference:

2018-047043 filed in JP on Mar. 14, 2018.

### BACKGROUND

### 1. Technical Field

The present invention relates to a semiconductor device and an apparatus.

### 2. Related Art

Conventionally, clamp circuits are provided for semiconductor switches that are connected to inductive loads. The clamp circuit prevents the breakdown of the semiconductor switch by clamping voltage that is applied to the semiconductor switch when the power supplied to the inductive load is cut off, to the clamp voltage (refer to Patent documents 1 to 4, for example).

Patent document 1: Japanese Patent Application Publication No. 2012-4979

Patent document 2: Japanese Patent Application Publication No. 2016-167693

Patent document 3: Japanese Patent Application Publication No. 2006-216651

Patent document 4: WO 2015/198435

However, the conventional apparatuses cannot change clamp voltage easily.

### SUMMARY

In order to solve the problem described above, a first aspect of the present invention provides a semiconductor device. The semiconductor device may include a semiconductor switch. The semiconductor device may include an exterior body housing a semiconductor switch. The semiconductor device may include a drain terminal that is electrically connected to a drain of the semiconductor switch and exposed through the exterior body. The semiconductor device may include a plurality of voltage clamp devices that are cascade-connected between the drain terminal and a gate of the semiconductor switch. The semiconductor device may include a voltage clamp terminal that is electrically connected between two of the plurality of voltage clamp devices and exposed through the exterior body.

The plurality of voltage clamp devices may be arranged inside the exterior body. The voltage clamp terminal, if connected to the drain terminal, may bypass any one or more of the plurality of voltage clamp devices on a path from the drain terminal to the gate.

At least one voltage clamp device may be provided in cascade between the voltage clamp terminal and a node between the two voltage clamp devices.

The number of voltage clamp devices that are positioned between the drain terminal and the node, among the plurality of voltage clamp devices, may be different from the number of the at least one voltage clamp device.

The semiconductor device may include the voltage clamp terminal and one or more additional voltage clamp terminals that are connected to a plurality of different nodes, each node being between any adjacent two of the plurality of voltage clamp devices.

The semiconductor device may further include a gate control circuit to control the gate of the semiconductor switch. The semiconductor device may further include a source terminal that is electrically connected to a source of the semiconductor switch and exposed through the exterior body.

A second aspect of the present invention provides an apparatus. The apparatus may include a positive power supply. The apparatus may include a semiconductor device of the first aspect. The apparatus may include an inductive load that is connected in series to the semiconductor device between the positive power supply and a ground.

The summary clause does not necessarily describe all necessary features of the embodiments of the present invention. The present invention may also be a sub-combination of the features described above.

### BRIEF DESCRIPTION OF THE DRAWINGS

FIG. 1 shows an apparatus according to the present embodiment.

FIG. 2 shows a current path with a voltage clamp terminal connected to a drain terminal.

FIG. 3 shows an appearance of a semiconductor device according to the present embodiment.

### DESCRIPTION OF EXEMPLARY EMBODIMENTS

Hereinafter, (some) embodiment(s) of the present invention will be described. The embodiment(s) do(es) not limit the invention according to the claims, and all the combinations of the features described in the embodiment(s) are not necessarily essential to means provided by aspects of the invention.

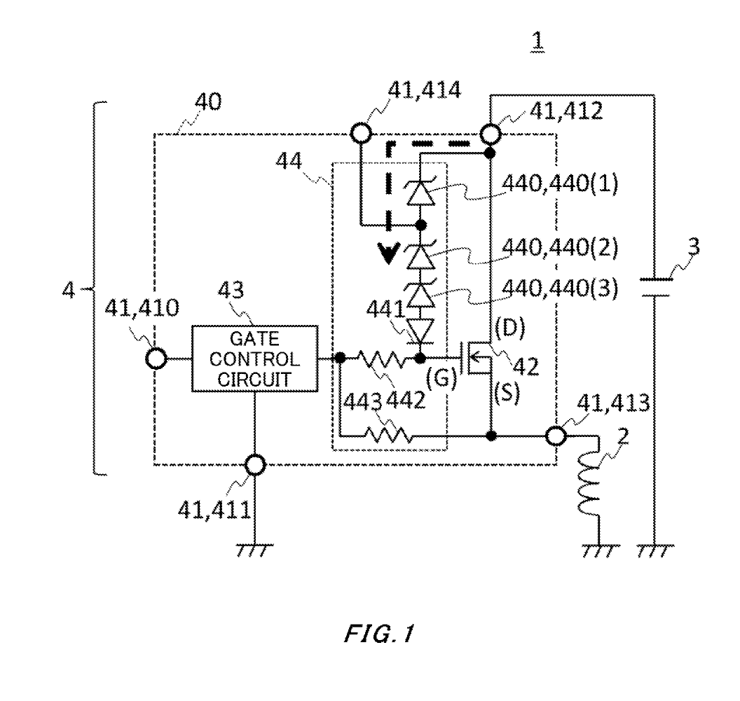

FIG. 1 shows an apparatus 1 according to the present embodiment. The apparatus 1 includes one or more inductive loads 2, a positive power supply 3, and a semiconductor device 4.

The one or more inductive loads 2 are connected in series to the semiconductor device 4 between the positive power supply 3 and a ground. As an example in the present embodiment, the inductive load 2 is connected between the semiconductor device 4 and the ground, but may be connected between the semiconductor device 4 and the positive power supply 3. Also, as an example in the present embodiment, one inductive load 2 is included in the apparatus 1. The inductive load 2 may be a valve such as a solenoid valve and a hydraulic valve, a motor, or a transformer.

The positive power supply 3 supplies power to the one or more inductive loads 2. For example, if one inductive load 2 is provided in the apparatus 1, the positive power supply 3 may supply power of 13 V and 1 A to the inductive load 2.

The semiconductor device 4 switches the power supplied to the inductive load 2. The semiconductor device 4 includes an exterior body 40, a plurality of terminals 41, a semiconductor switch 42, a gate control circuit 43, and a clamp circuit 44.

The exterior body 40 houses a semiconductor switch 42. The exterior body 40 may have the semiconductor switch 42 tightly sealed therein. The exterior body 40 may be a case-typed package that is obtained by injecting a sealing resin into a transfer-mold-typed package or case, or the like.

The plurality of terminals 41 are each exposed through the exterior body 40. For example, the plurality of terminals 41 have: a terminal to receive, from outside, an input signal to the gate control circuit 43, or “a control terminal 410”; a terminal connected to the ground, or “a ground terminal 411”; a terminal connected to the positive electrode of the positive power supply 3, or “a drain terminal 412”; a terminal connected to the inductive load 2, or “a source terminal 413”; and a terminal connectable to the drain terminal 412, or “a voltage clamp terminal 414”.

The semiconductor switch 42 controls the power supplied to the inductive load 2. As an example in the present embodiment, the semiconductor switch 42 is connected to the drain terminal 412 at the drain thereof, the source terminal 413 at the source thereof, and the gate control circuit 43 at the gate thereof. The semiconductor switch may be a field effect transistor such as a MOSFET (metal-oxide-semi-conductor field-effect transistor). Alternatively, the semiconductor switch 42 may be an IGBT (Insulated Gate Bipolar Transistor).

The gate control circuit 43 controls the gate of the semiconductor switch 42. The gate control circuit 43 may be provided between the gate of the semiconductor switch 42 and the control terminal 410, and may supply a control signal based on a signal that is input via the control terminal 410, to the gate of the semiconductor switch 42 via a resistor 442 described below. The gate control circuit 43 may be connected to the ground via the ground terminal 411. The gate control circuit 43 may be arranged inside the exterior body 40.

The clamp circuit 44 clamps voltage that is applied to the semiconductor switch 42 when the power supplied to the inductive load 2 is cut off, to prevent the semiconductor switch 42 from its breakdown. The clamp circuit 44 has: a plurality of voltage clamp devices 440; a diode 441; and one or more (two, as an example in the present embodiment) resistors 442 and 443. As an example in the present embodiment, all the constituents of the clamp circuit 44 are arranged inside the exterior body 40.

The plurality of voltage clamp devices 440 are cascade-connected between the drain terminal 412 and the gate of the semiconductor switch 42. As an example in the present embodiment, three voltage clamp devices 440, or “voltage clamp devices 440(1) to 440(3)”, are provided in the clamp circuit 44.

The voltage clamp devices 440 may allow no current flow if voltage smaller than reference voltage is applied, and may allow current flow if voltage greater than or equal to the reference voltage is applied. As an example in the present embodiment, the voltage clamp devices 440(1) to 440(3) allow current flow, if voltages greater than or equal to reference voltages (V1 to V3) are respectively applied. Thereby, the plurality of voltage clamp devices 440, as a whole, may clamp the voltage between the both-end voltages of the whole of the plurality of voltage clamp devices 440 to the clamp voltage Vc, by allowing no current flow if voltage smaller than clamp voltage, or “breakdown voltage” Vc is applied, and allowing current flow if voltage greater than or equal to the clamp voltage Vc is applied. The clamp voltage may be a total sum of the reference voltages V1 to V3 of respective voltage clamp devices 440, and may be 50 V, as an example. The reference voltages V1 to V3 may be equal to or different from each other. As an example in the present embodiment, each voltage clamp device 440 may be a Zener diode, and its cathode may be directed toward the drain terminal 412. Note that each voltage clamp device 440 may be another diode such as a trigger diode, or may be a device other than a diode.

A voltage clamp terminal 414 is electrically connected between any adjacent two of the plurality of voltage clamp devices 440. Thereby, if the voltage clamp terminal 414 is connected to the drain terminal 412, any one or more of the plurality of voltage clamp devices 440 is bypassed on a path from the drain terminal 412 to the gate of the semiconductor switch 42. As an example in the present embodiment, the voltage clamp terminal 414 is connected between the voltage clamp devices 440(1) and 440(2), which are the closest two of the voltage clamp devices 440 to the drain terminal 412, and if the voltage clamp terminal 414 is connected to the drain terminal 412, the voltage clamp device 440(1) is bypassed.

The diode 441 is a diode for temperature compensation for the voltage clamp devices 440. The diode 441 may be connected in series to the plurality of voltage clamp devices 440 between the drain terminal 412 and the gate of the semiconductor switch 42. The cathode of the diode 441 may be directed toward the gate.

The resistors 442 and 443 are connected in series between the gate of the semiconductor switch 42 and the source terminal 413. The resistors 442 and 443 may generate gate voltage depending on current flowing between the source terminal 413 and the gate of the semiconductor switch 42. As an example in the present embodiment, the resistor 442 is provided between the gate control circuit 43 and the gate of the semiconductor switch 42, and also functions as a gate resistance. Note that a diode to prevent current from flowing from the source terminal 413 to the gate control circuit 43 may be provided between the resistor 442 and the source terminal 413.

The following describes an operation in a case where the semiconductor switch 42 cuts off the power supplied to the inductive load 2. When the semiconductor switch 42 cuts off the power supplied to the inductive load 2, the inductive load 2 tries to maintain the current by self-induction to make the current flow from the source terminal 413 side to the ground side, and, as a result, potential of the source terminal 413 decreases. The source terminal 413 may have negative potential resultantly. Thereby, device voltage applied to the semiconductor switch 42 becomes greater. When the device voltage reaches the clamp voltage Vc, the voltage clamp devices 440(1) to 440(3) clamp the device voltage to the clamp voltage Vc and make weak current flow (refer to the bold broken-lined arrow in the figure). Thereby, the gate potential of the semiconductor switch 42 becomes higher than the source potential thereof due to the resistors 442 and 443, and, as a result, the gate is slightly turned ON to allow weak current flow through the semiconductor switch 42. As a result, increase in device voltage of the semiconductor switch 42 is reduced, and the semiconductor switch 42 is prevented from its breakdown. Also, the semiconductor switch 42 allows only weak current flow and thus functions as a resistor, and converts electrical energy (=voltage×current×time) into heat. Thereby, stored energy in the inductive load 2 dissipates as heat, and, when the device voltage becomes smaller than the clamp voltage Vc, current no longer flows through the voltage clamp devices 440(1) to 440(3), resulting in the gate of the semiconductor switch 42 turned off.

The following describes an operation in a case where the semiconductor switch 42 cuts off the power supplied to the inductive load 2 with the voltage clamp terminal 414 connected to the drain terminal 412, will be described.

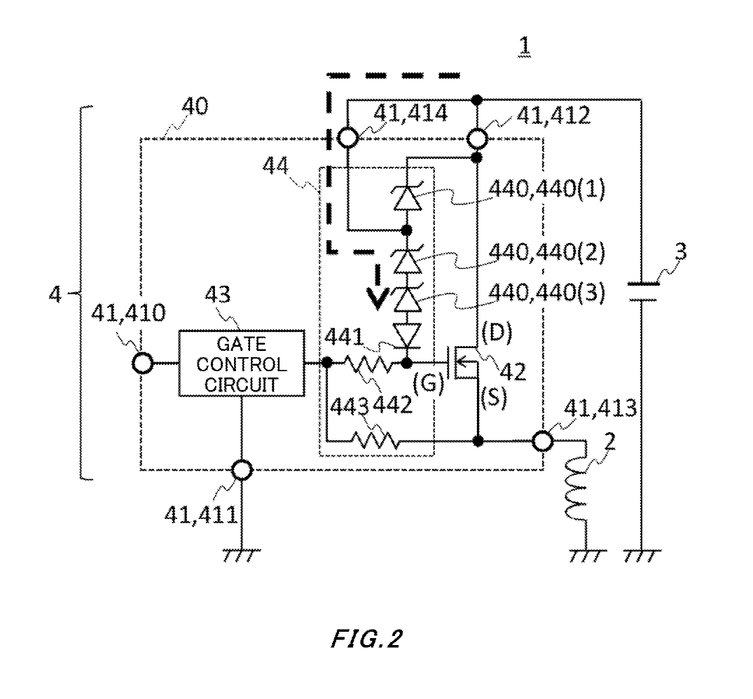

FIG. 2 shows the current path with the voltage clamp terminal 414 connected to the drain terminal 412. A bold broken-lined arrow in the figure represents a current path.

When the voltage clamp terminal 414 is connected to the drain terminal 412, as an example in the present embodiment, the voltage clamp device 440(1) is bypassed on a path from the drain terminal 412 to the gate, and thus clamp voltage Vc (=V1+V2+V3) is reduced, by voltage of the voltage clamp device 440(1), to be Vc′ (=V2+V3). Thus, when the device voltage reaches the clamp voltage Vc′ (where, Vc′<Vc), the voltage clamp devices 440(1) to 440(3) clamp the device voltage to the clamp voltage Vc′ and make weak current flow (refer to the bold broken-lined arrow in the figure). Thereby, similarly to the above description, weak current flows through the semiconductor switch 42 to prevent its breakdown, and electrical energy (=voltage×current×time) is converted into heat at the semiconductor switch 42.

Here, when the clamp voltage is small, potential difference between the drain terminal 41 and the inductive load 2 is smaller than when the clamp voltage is great, and thus the stored energy of the inductive load 2 dissipates as heat energy over relatively long time, which causes small amount of heat generation at the semiconductor switch 42. Accordingly, when the voltage clamp terminal 414 is connected to the drain terminal 412, the dissipation time of the stored energy of the inductive load 2 becomes longer, when the voltage clamp terminal 414 is not connected, and the amount of heat generation becomes smaller.

According to the semiconductor device 4 above, the drain terminal 412 is electrically connected to the drain of the semiconductor switch 42 and exposed through the exterior body 40, and the voltage clamp terminal 414 is electrically connected between any two of the voltage clamp devices 440 and exposed through the exterior body 40. Accordingly, by connecting or disconnecting the drain terminal 412 and the voltage clamp terminal 414, the number of the voltage clamp devices 440 on the path from the drain terminal 412 to the gate, and, as a result, clamp voltage of the clamp circuit 44 can be changed easily. Accordingly, according to the magnitude of the self-inductance or a driving mode of the inductive load 2, or heat resistance of the semiconductor switch 42, etc., the dissipation time of the stored energy of the inductive load 2 and/or the amount of heat generation of the semiconductor switch 42 due to the energy can be changed easily.

Also, the plurality of voltage clamp devices 440 are arranged inside the exterior body 40. Accordingly, the clamp voltage can be easily changed without increasing the complexity of an externally attached circuit of the exterior body 40.

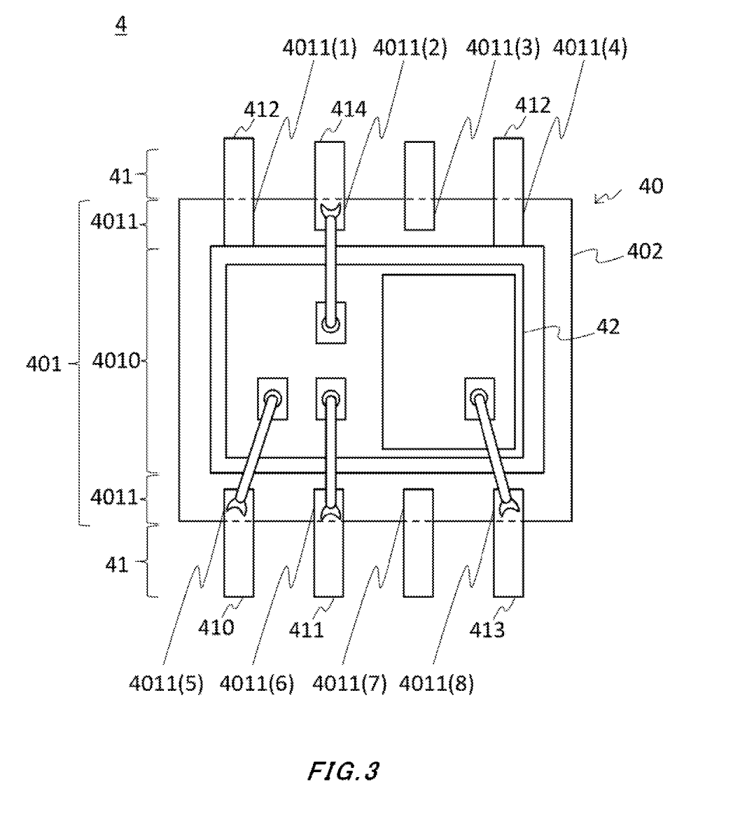

FIG. 3 shows an appearance of a semiconductor device 4 according to the present embodiment. As an example in the present embodiment, the exterior body 40 of the semiconductor device 4 has a lead frame 401 including the semiconductor switch 42 thereon, and a mold resin portion 402 sealing the semiconductor switch 42 and the lead frame 401 therein. Note that, as an example in the present embodiment, the semiconductor switch 42 is a vertical MOSFET that has the gate and the source on the upper surface side, and the drain on the lower surface side. Also, although not illustrated in FIG. 3, the exterior body 40 may cover the upper surface of the semiconductor switch 42.

The lead frame 401 may be formed from metals having excellence in heat dissipation and conductivity (copper, as an example), or the like. For example, the lead frame 401 may be formed by press working metal plates. The lead frame 401 may have a lead frame body 4010 and a plurality of lead frame segments 4011.

The lead frame body 4010 is formed in a rectangular plate shape, and may support the semiconductor switch 42 on the upper surface at its central portion. A solder (not shown) may exist between the semiconductor switch 42 and the lead frame body 4010.

The plurality of lead frame segments 4011 are each formed in a plate shape and may be arranged apart from each other. Each lead frame segment 4011 may be arranged, as an example, on the same surface as that of the lead frame body 4010.

As an example in the present embodiment, the lead frame 401 may have eight lead frame segments 4011(1) to 4011(8). Among these, the lead frame segments 4011(1), 4011(4) may be integrated with the drain terminal 412 outside the exterior body 40, and may be integrated with the lead frame body 4010 inside the exterior body 40 to be connected to the drain on the lower surface of the semiconductor switch 42. The lead frame segment 4011(2) may be integrated with the voltage clamp terminal 414 outside the exterior body 40, and may be connected between the voltage clamp devices 440(1) and 440(2) inside the exterior body 40. Here, the lead frame segment 4011(2) integrated with the voltage clamp terminal 414 and the lead frame segment 4011(1) integrated with the drain terminal 412 may be connectable to each other via a copper wire etc., and may be arranged adjacent to each other, as an example. The lead frame segments 4011(5), 4011(6) may be respectively integrated with the control terminal 410, the ground terminal 411 outside the exterior body 40, and may be each connected with the gate control circuit 43 inside the exterior body 40. The lead frame segment 4011(8) may be integrated with the source terminal 413 outside the exterior body 40, and may be connected to the source of the semiconductor switch 42 inside the exterior body 40. Note that the lead frame segments 4011(3), 4011(7) may be respectively integrated with NC (No Contact) terminals.

The mold resin portion 402 makes the semiconductor switch 42 and the lead frame 401 etc. mold-sealed. The mold resin portion 402 may be formed from solidified resin. The resin to use may include, but not limited to, insulating thermosetting resins, such as epoxy resin, maleimide resin, polyimide resin, isocyanate resin, amino resin, phenol resin, silicone-based resin, for example. The resin may contain additives such as an inorganic filler.

Note that, in the embodiment described above, it has been described that the voltage clamp terminal 414 is connected between any adjacent two of the voltage clamp devices 440, but it may also be connected via at least one other voltage clamp device. For example, at least one other voltage clamp device may be provided in cascade between the voltage clamp terminal 414 and a node between two of the voltage clamp devices 440 (the voltage clamp devices 440(1) and 440(2), as an example), or “a connection node of the voltage clamp terminal 414”. In this case, the difference between clamp voltages Vc and Vc′, which are changed by connecting or disconnecting the drain terminal 412 and the voltage clamp terminal 414, can be set easily. Here, the number of the voltage clamp devices 440 positioned between the connection node of the voltage clamp terminal 414 and the drain terminal 412 may be different from the number of other voltage clamp devices between the voltage clamp terminal 414 and the connection node. Thereby, the clamp voltage can be surely changed by connecting and disconnecting the drain terminal 412 and the voltage clamp terminal 414.

Also, it has been described that the semiconductor device 4 includes one of the voltage clamp terminal 414, but it may also include a plurality of the voltage clamp terminals 414 connected to different nodes, each node being between any adjacent two of the voltage clamp devices 440. In this case, by selecting a different one of the voltage clamp terminals 414 to be connected to the drain terminal 412, the clamp voltage can be changed among a plurality of voltages. Also, by connecting two of the voltage clamp terminals 414 to each other, the number of the voltage clamp devices 440 on the path from the drain terminal 412 to the gate of the semiconductor switch 42, and, as a result, clamp voltage can be changed easily.

Also, it has been described that the gate control circuit 43 is arranged inside the exterior body 40, but may be arranged outside the exterior body 40. In this case, a gate terminal to receive a control signal from the gate control circuit 43 and supply it to the gate of the semiconductor switch 42, may be provided in the exterior body 40. Also, the gate control circuit 43 may not be provided in the semiconductor device 4.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A semiconductor device comprising:
a semiconductor switch;
an exterior body housing the semiconductor switch;
a drain terminal that is electrically connected to a drain of the semiconductor switch and exposed through the exterior body;
a plurality of voltage clamp devices that are cascade-connected between the drain terminal and a gate of the semiconductor switch; and
a voltage clamp terminal that is electrically connected between two of the plurality of voltage clamp devices and exposed through the exterior body.

2. The semiconductor device according to claim 1, wherein the plurality of voltage clamp devices are arranged inside the exterior body.

3. The semiconductor device according to claim 1, wherein the voltage clamp terminal, if connected to the drain terminal, bypasses any one or more of the plurality of voltage clamp devices on a path from the drain terminal to the gate.

4. The semiconductor device according to claim 1, wherein at least one voltage clamp device is provided in cascade between the voltage clamp terminal and a node between the two voltage clamp devices.

5. The semiconductor device according to claim 4, wherein a number of voltage clamp devices that are positioned between the drain terminal and the node among the plurality of voltage clamp devices is different from a number of the at least one voltage clamp device.

6. The semiconductor device according to claim 1, comprising the voltage clamp terminal and one or more additional voltage clamp terminals that are connected to a plurality of different nodes, each node being between any adjacent two of the plurality of voltage clamp devices.

7. The semiconductor device according to claim 1, further comprising:
a gate control circuit to control the gate of the semiconductor switch; and
a source terminal that is electrically connected to a source of the semiconductor switch and exposed through the exterior body.

8. The semiconductor device according to claim 1, wherein each of the plurality of voltage clamp devices is Zener diodes.

9. An apparatus comprising:
a positive power supply;
the semiconductor device according to claim 1; and
an inductive load that is connected in series to the semiconductor device, between the positive power supply and a ground.
